(19) United States
(12) Patent Application Publication
(10) Pub. No.: US 2026/0105942 A1
(43) Pub. Date: Apr. 16, 2026

(54) Memory Sense Amplifier

(71) Applicant: GlobalFoundries U.S. Inc., Malta, NY (US)

(72) Inventors: Juhan Kim, Santa Clara, CA (US); Mahbub Rashed, Santa Clara, CA (US)

(21) Appl. No.: 18/912,860

(22) Filed: Oct. 11, 2024

(51) Int. Cl. G11C 7/08; G11C 7/12; G11C 7/14

(52) U.S. Cl. CPC G11C 7/08; G11C 7/12; G11C 7/14

(57) ABSTRACT

The present disclosure relates to a memory sense amplifier and, more particularly, to a non-volatile memory sense amplifier and methods of use. The structure includes: a first stage amplifier comprising a plurality of non-volatile memory cells connecting to a bit line; a second stage amplifier connecting to the first stage amplifier and a common reference node; and a reference unity gain amplifier connecting to the second stage amplifier through the common reference node and receiving a voltage bias from the first stage amplifier, wherein the reference unity gain amplifier is connected to provide a reference voltage to the second stage amplifier.

### BACKGROUND

The present disclosure relates to a memory sense amplifier and, more particularly, to a non-volatile memory sense amplifier and methods of use.

A sense amplifier is part of the read circuitry used when data is read from the memory. The sense amplifier will sense the low power signals from a bitline that represents a data bit (1 or 0) stored in a memory cell, and amplify the small voltage swing to recognizable logic levels. In this way, data can be interpreted by logic outside of the memory.

### SUMMARY

In an aspect of the disclosure, a structure comprises: a first stage amplifier comprising a plurality of non-volatile memory cells connecting to a bit line; a second stage amplifier connecting to the first stage amplifier and a common reference node; and a reference unity gain amplifier connecting to the second stage amplifier through the common reference node and receiving a voltage bias from the first stage amplifier, wherein the reference unity gain amplifier is connected to provide a reference voltage to the second stage amplifier.

In an aspect of the disclosure, a structure comprises: a first stage amplifier comprising memory cells in parallel and connecting to a bitline; a second stage amplifier comprising a plurality of differential amplifiers connecting to a common node and receiving a voltage signal from the memory cells of the first stage amplifier; and a reference unity gain amplifier receiving a voltage bias from the first stage amplifier and providing a reference voltage to the second stage amplifier through the common node, wherein the reference unity gain amplifier is connected to provide a reference voltage to the second stage amplifier.

In an aspect of the disclosure, a method comprises: providing a first signal form a first stage amplifier to a second stage amplifier, the second stage amplifier comprising a plurality of differential sense amplifiers; providing a voltage bias from the first stage amplifier to a reference unity gain amplifier; providing a second signal from the reference unity gain amplifier to the second stage amplifier, wherein the reference unity gain amplifier is connected to provide a reference voltage to the second stage amplifier; sensing a difference between the first signal and the second signal in the second stage amplifier; amplifying the sensed difference in the second stage amplifier; and providing a signal to a data line sense amplifier based on the sensed difference.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a circuit diagram used in non-volatile memory in accordance with aspects of the present disclosure.

FIGS. 2 and 3 show timing diagrams with the implementation of a sense amplifier in accordance with aspects of the present disclosure.

FIG. 4 shows a representative memory structure in accordance with aspects of the present disclosure.

### DETAILED DESCRIPTION

The present disclosure relates to a memory sense amplifier and, more particularly, to a non-volatile memory sense amplifier and methods of use. More specifically, the present disclosure provides a non-volatile memory sense amplifier which reduces power consumption. The non-volatile memory sense amplifier also reduces an overall footprint or chip area of a sense amplifier.

In more specific embodiments, the non-volatile memory sense amplifier comprises a multi-stage sense amplifier sharing a voltage reference circuit. The multi-stages may be, for example, at least two stages. The first stage of the sense amplifier includes a read unity gain amplifier and the second stage of the sense amplifier includes a differential amplifier. The non-volatile memory sense amplifier also comprises a voltage reference generator (e.g., unity gain amplifier) shared by multiple-stage sense amplifiers. In embodiments, a plurality of non-volatile memory cells may connect to a bit line, where the non-volatile memory cells store one of two resistance values R0, R1. The read unity gain amplifier connects to the bit line, and the differential amplifier connects to the read unity gain amplifier and to a common reference node. The voltage reference generator is composed of another unity gain amplifier connecting to a middle resistance value of the two resistance values. The voltage reference generator provides a reference voltage to a group of the second stage amplifiers through the common reference node. A decoupling capacitor may connect to the common reference node.

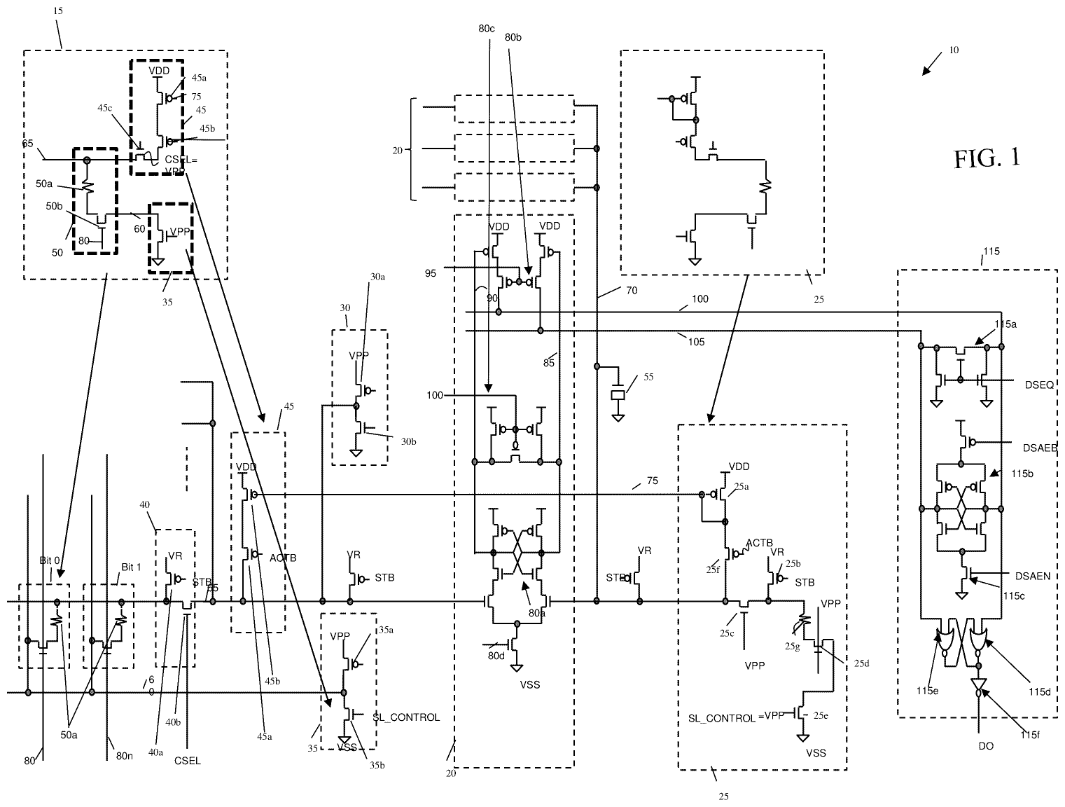

FIG. 1 shows a circuit diagram used in non-volatile memory in accordance with aspects of the present disclosure. In embodiments, the circuit 10 may be a sense amplifier for non-volatile memory. The circuit 10 shown in FIG. 1 includes a read unity gain amplifier 15, a plurality of sense amplifiers 20 (e.g., differential amplifiers) and a reference unity gain amplifier 25 (e.g., voltage reference generator), in addition to a write driver 30, a sense line (SL) driver 35 and a column decoder 40. In embodiments, the read unity gain amplifier 15 may be a first stage amplifier connecting to the bitline 65 and the sense amplifiers 20 may be second stage differential amplifiers connecting to the first stage amplifier (e.g., read unity gain amplifier 15) and to a common reference node 70. The sense amplifiers 20 may also connect to a data line sense amplifier 115 and the reference unity gain amplifier 25 through the common reference node 70. As to the latter point, in this way, the reference unity gain amplifier 25 may be shared with multiple sense amplifiers 20.

In embodiments, the sense line (SL) driver 35 may be a component of the read unity gain amplifier 15, which also includes additional circuitry 45, 50 as further described herein. In embodiments, the sense line (SL) driver 35 may be connected to the sense line 60 and the column decoder 40 may be connected to a bitline 65. The additional circuitry 50 (e.g., memory cell) of the read unity gain amplifier 15 may also be connected to the sense line 60 and the bitline 65; whereas the additional circuitry 45 may be connected to the bitline 65 and signal line 70. The signal line 70 may provide a voltage bias (e.g., mid-range resistance value) to the reference unity gain amplifier 25 as described in more detail herein.

As shown further in the circuit 10 of FIG. 1, the reference unity gain amplifier 25 may be common to each of the sense amplifiers 20, in addition to connecting to the read unity amplifier 15, e.g., circuitry 45 of the read unity amplifier 15. For example, the reference unity gain amplifier 25 may be connected to each of the sense amplifiers 20 through the common reference node 70. The reference unity gain amplifier 25 may also connect directly to the read unity gain amplifier 15 and, more specifically, the circuit 45 of the read unity gain amplifier 15 through the line 75. In this way, the common reference unity gain amplifier 25 can provide significant area savings, while also reducing power consumption. Also, in this way, the reference unity gain amplifier 25 may be provided with a voltage bias (VB), e.g., mid-range resistance value of the different resistance values R0 and R1 of resistors 50a, through line 75.

As further shown in FIG. 1, the plurality of sense amplifiers 20 may be commonly connected to a decoupling capacitor 55 through the common reference node 70. In embodiments, the decoupling capacitor 55 may be used to decouple (i.e. prevent electrical energy from transferring to) between the different sense amplifiers 20 and the reference unity gain amplifier 25. In this way, noise caused by any of the sense amplifiers 20 or the reference unity gain amplifier 25 will be shunted through the capacitor 55, reducing its effect on the circuit, e.g., other sense amplifiers 20 or the reference unity gain amplifier 25.

Still referring to FIG. 1, in embodiments, the write driver 30 includes transistors 30a, 30b (in series), the sense line (SL) driver 35 includes transistors 35a, 35b (in series) and the column decoder 40 includes transistors 40a, 40b (in series). In embodiments, the transistors 30a, 35a, 40a may be PFETs and the transistor 30b, 35b, 40b may be NFETs. The write driver 30 and the column decoder 40 may be connected to the bitline 65 and the sense line (SL) driver 35 may be connected to the sense line 60. In a read operation (e.g., sense operation), the transistors 30a, 30b of the write driver 30 and the transistors 35a of the sense line (SL) driver 35 are off; whereas the transistor 35b of the sense line (SL) driver 35 is on. Accordingly, during the read operation, the write driver 30 is off. In the write operation, on the other hand, the transistors 30a, 30b of the write driver 30 and the transistors 35a of the sense line (SL) driver 35 are on; whereas the transistor 35b of the sense line (SL) driver 35 is off.

In further embodiments, an input of voltage reference VR may be fed into the column decoder 40 and an input signal STB may be fed into the gate body of the PFET 40a of the column decoder 40. In embodiments, a column select signal (CSEL) may be fed to the gate body of the transistor 40b of the column decoder 40. An input voltage VPP (e.g., peak to peak voltage) may be provided to both the write driver 30 and the sense line (SL) driver 35, with an output of the sense line (SL) driver 35 being VSS (e.g., ground or negative supply voltage). A sense line (SL) control signal (SL_control) may be fed into the transistor 35b of the sense line driver 35. In embodiments, both the CSEL and SL_control may be equal to VPP. Also, in embodiments, input signal STB may be equal to VDD. In embodiments, VDD may be the working voltage of the circuit (e.g., integrated circuit which implements the memory device).

The read unity gain amplifier 15 further includes circuitry 45, 50. In embodiments, the circuitry 45 includes a transistors 45a, 45b, 45c (in series). The transistors 45a, 45b may be PFETs and the transistor 45c may be an NFET. In the read operation, an active load, e.g., VDD, may be applied to the circuitry 45, with the transistors 45a, 45b being on. The gate body of the transistor 45a may be connected to line 75 which also provides the bias voltage (VB) to the common reference unity gain amplifier 25. The gate body of the transistors 45b may be held at 0V (e.g., VSS) during the read operation. As noted previously, VSS is ground or a negative supply voltage. The input of the transistor 45c may be connected to the bit line 65 and the gate body of the transistor 45c may be connected to the column select signal (CSEL). In embodiments, the column select signal (CSEL) may be equal to the input voltage VPP (e.g., peak to peak voltage).

The circuitry 50 (e.g., memory cell) of the read unity gain amplifier 15 may be representative of multiple memory cells, each of which are connected between the bit line 65 and wordlines 80 to 80n (e.g., WL0, WL1, etc.). In embodiments, the memory cells may be a plurality of non-volatile memory cells connecting to the bit line 65, and which store one of two resistance values (R0, R1) with access transistor 50b. For example, the circuit 50 includes a resistor 50a and a transistor (e.g., NFET) 50b, in series. The resistor 50a of each memory cell may be in parallel with a resistance value of R0 or R1, where R0<R1. For example, R0 may be 2 Kohm and R1 may be 5 Kohm. For purposes of this disclosure, at bit0, the transistor 50a is set at R0 and, at bit1, the transistor 50a is set at R1. The mid-range resistance value (voltage bias VB) (e.g., (R1+R0)/2) and which may be fed to the reference unity gain amplifier 25 through line 75 (through circuit 45).

FIG. 1 further shows the sense amplifiers 20, e.g., differential amplifiers, each of which comprises a plurality of transistors 80a, 80b, 80c, 80d as is known in the art. For example, in embodiments, the transistors 80a, 80b, 80c are arranged to detect a difference between an incoming voltage (SA) from the bit line 65 (e.g., from the read unity gain amplifier 15) and a reference sense amplified signal (RSA) from the reference unity gain amplifier 25. The difference of these signals can be amplified in the sense amplifiers 20 which, in turn, can be used to feed a signal to the data line sense amplifier through lines 95, 100.

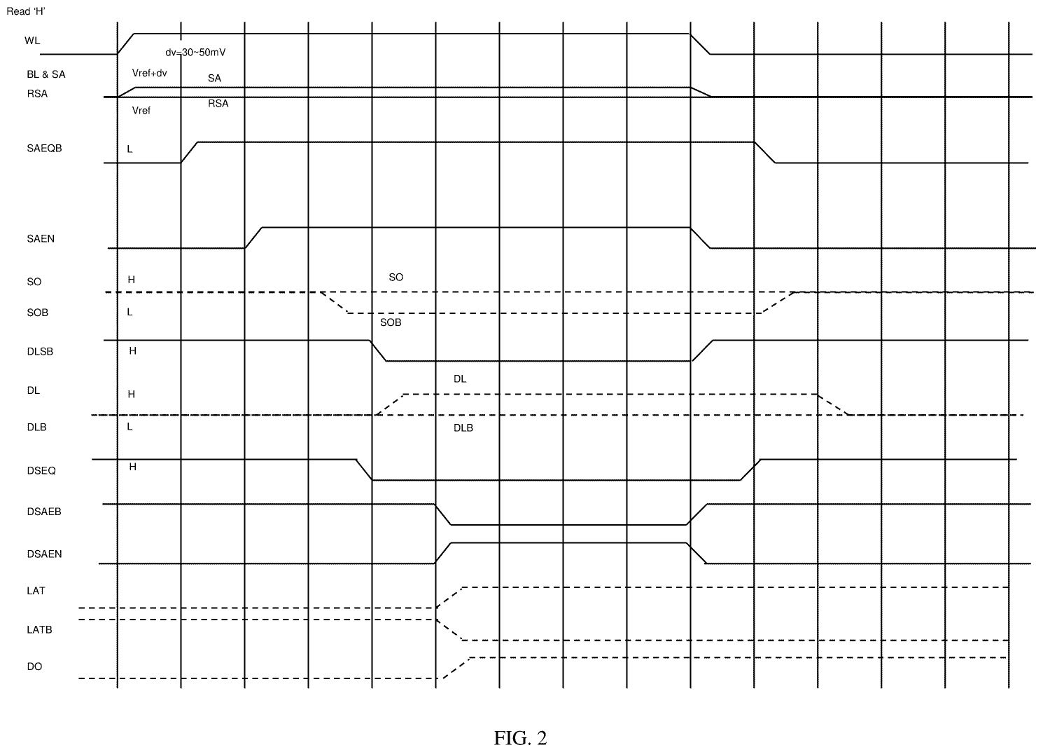

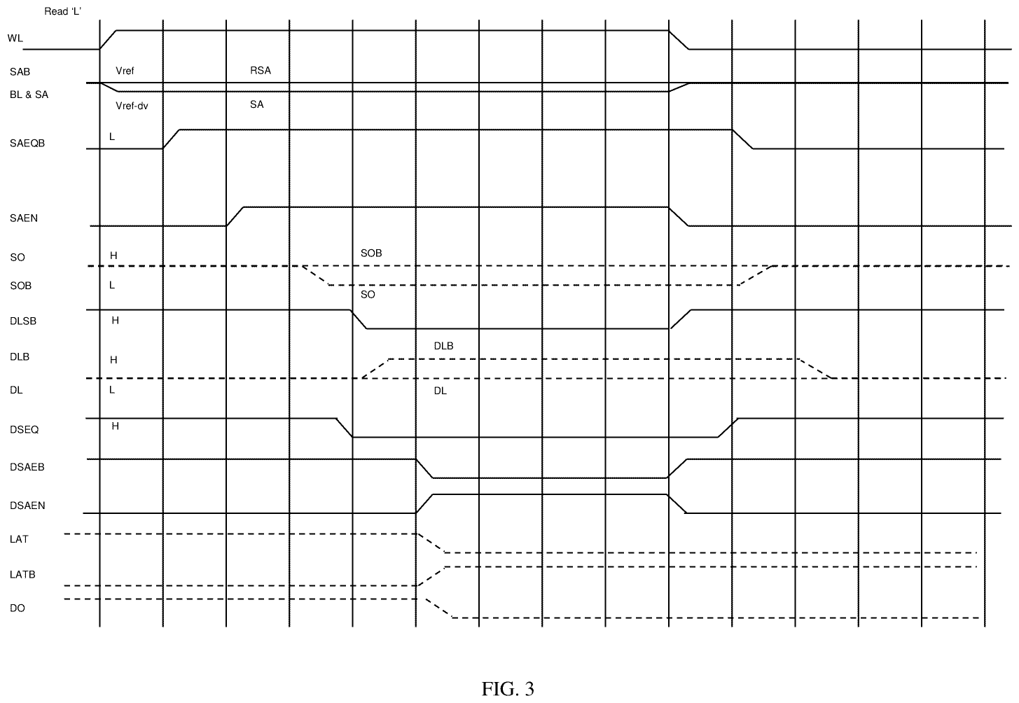

In embodiments, the transistors 80a, 80b, 80c may be connected between lines 85, 90, which each are connected between input VDD and VSS (ground). In embodiments, the line 85 is a sense amplifier output line (SO) and line 90 is a low signal (e.g., off) sense amplifier output line (SOB). The input line to transistor 80d is a high signal (enable signal) (e.g., SAEN). As discussed with respect to the timing charts of FIGS. 2 and 3, when the incoming voltage (SA) is low and the reference sense amplified signal (RSA) is high, the sense amplifier output line (SO) is low and the sense amplifier output line (SOB) is high; whereas when the incoming voltage (SA) is high and the reference sense amplified signal (RSA) is low, the sense amplifier output line (SO) is high and the sense amplifier output line (SOB) is low.

In embodiments, the transistors 80b are connected to line 95 and transistors 80c are connected to line 100. In embodiments, line 95 is a data sense line with a low signal, e.g., 0 volts (DLSB) and line 100 is sense amplifier equalization line with a low signal, e.g., 0 volts (SAEQB). The output of the transistors 80b (e.g., output lines 105, 110) are fed to the data line sense amplifier 115. In embodiments, the output 105 is a data line with a high signal (DL) and the output 110 is a data line with a low signal, e.g., 0 volts, (DLB).

The reference unity gain amplifier 25 includes a plurality of transistors 25a, 25b, 25c, 25d, 25e, 25f and a resistor 25g. In embodiments, the resistor 25g may be at a fixed resistance, e.g., 4 Kohms. The transistors 25a, 25f, 25c, 25d, 25e, 25f and resistor 25g are connected between VDD and VSS. The transistors 25a, 25b, 25f may be PEFTs and transistors 25c, 25d, 25e may be NFETs. In the read operation, the transistors 25a, 25f, 25c, 25d, 25e, 25f are on. The input to the transistor 25b is the voltage reference VR and the input to the transistor 25g and to the gate body of the transistor 25c is VPP. Moreover, the input to the gate body of the transistor 25e is the control signal (SL_control), which is equal to VPP. The input to the transistor 25f and the gate body of the transistor 25a is the voltage bias (VB) of line 75, e.g., a mid-range resistance value (e.g., (R1+R0)/2) of the memory cells. The gate body of the transistor 25b connects to the input signal STB and the gate body of the transistor 25f connects to VSS.

The data line sense amplifier 115 includes a plurality of transistors 115a, 115b, 115c and latches 115d, 115e connecting between lines 95, 100, e.g., providing high signal data line (DL) and a low signal data line, e.g., 0 volts, (DLB). The gate bodies of the transistors 115a connect to DSEQB and the gate bodies of the upper transistor and the lower transistor of the transistors 115b connect to a data line of the sense amplifier with a low signal (DSAEB) and data line of the sense amplifier with a high signal, e.g., enable signal (DSAEN), respectively. The input of the latch 115e is the low signal data line (DLB) and the output of the latch 115d (e.g., LATB). Similarly, the input of the latch 115e is the high signal data line (DL) and the output of the latch 115e (LAT). The output of the latch 115d is fed into diode 115f. The output of the diode (e.g., the data line sense amplifier 115) is DO.

FIGS. 2 and 3 show timing diagrams with the implementation of a sense amplifier in accordance with aspects of the present disclosure. FIG. 2 is representative of a read operation when the resistor 50a is set at R1 (higher resistance) and FIG. 3 is representative of a read operation when the resistor 50a is set at of R0 (lower resistance). As shown in FIG. 2, when the word line WL goes high, the following occurs: (i) bitline SA goes low, (ii) RSA, SAEN and DSAEN go high, (iii) SAEQB goes from low to high, (iv) SO stays high and SOB goes low, (v) DL stays low, (vi) DLSB, DSEQ and DSAEB go from high to low, and (vii) DLB goes high.

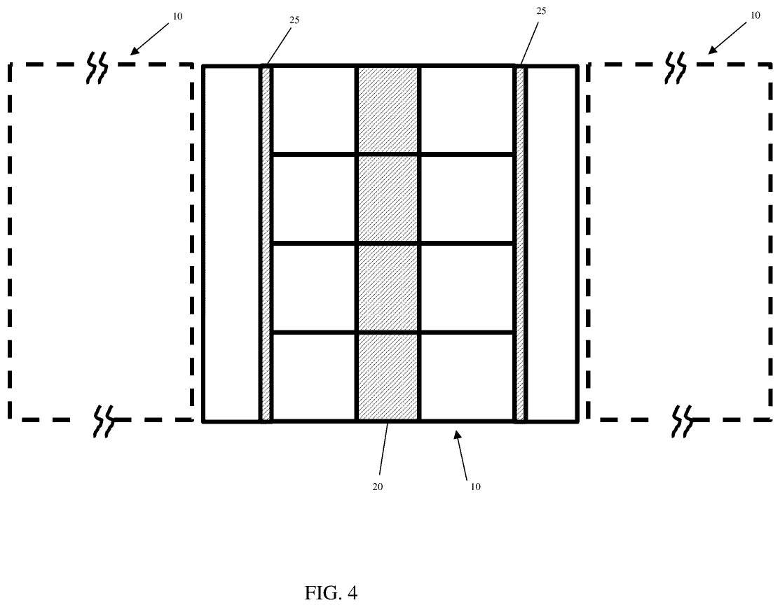

FIG. 4 shows a representative memory structure in accordance with aspects of the present disclosure. The memory structure includes an array of cells 10, each of which includes sense amplifiers 20 and reference unity gain amplifier 25 in a group. In embodiments, in this representation, the sense amplifiers 20 and reference unity gain amplifier 25 will share common contacts and layers. A voltage reference generator is placed under column decoder (not shown).

The non-volatile memory sense amplifier of the present disclosure can be manufactured in a number of ways using a number of different tools. In general, though, the methodologies and tools are used to form structures with dimensions in the micrometer and nanometer scale. The methodologies, i.e., technologies, employed to manufacture the non-volatile memory sense amplifier of the present disclosure have been adopted from integrated circuit (IC) technology. For example, the structures are built on wafers and are realized in films of material patterned by photolithographic processes on the top of a wafer. In particular, the fabrication of the non-volatile memory sense amplifier uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

The non-volatile memory sense amplifier can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The circuit as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a first stage amplifier comprising a plurality of non-volatile memory cells connecting to a bit line;
a second stage amplifier connecting to the first stage amplifier and a common reference node; and
a reference unity gain amplifier connecting to the second stage amplifier through the common reference node and receiving a voltage bias from the first stage amplifier, wherein the reference unity gain amplifier is connected to provide a reference voltage to the second stage amplifier.

2. The structure of claim 1, wherein the non-volatile memory cells store one of two resistance values with an access transistor.

3. The structure of claim 2, wherein the one of two resistance values comprises a high resistance value R1 and a low resistance value R0.

4. The structure of claim 3, wherein the voltage bias received by the reference unity gain amplifier comprises a mid-range resistance value of the high resistance value R1 and the low resistance value R0.

5. The structure of claim 1, wherein the first stage amplifier comprises a read unity gain amplifier connecting to the bitline and which comprises the plurality non-volatile memory cells in parallel.

6. The structure of claim 1, wherein the second stage amplifier comprises a plurality of differential amplifiers connecting to the first stage amplifier and the common reference node.

7. The structure of claim 6, further comprising a decoupling capacitor connecting to the common reference node.

8. The structure of claim 7, wherein the decoupling capacitor connects to each of the plurality of differential amplifiers and the reference unity gain amplifier.

9. The structure of claim 6, wherein the reference unity gain amplifier provides a signal to each of the plurality of differential amplifiers through the common reference node.

10. The structure of claim 1, wherein the reference unity gain amplifier is shared amongst multiple differential amplifiers of the second stage amplifier.

11. The structure of claim 10, wherein the second stage amplifier amplifies the difference and provides a signal to a data line sense amplifier.

12. The structure of claim 1, wherein the second stage amplifier receives signals from both the first stage amplifier and the reference unity gain amplifier, and the second stage amplifier detects a difference in the signals.

13. A structure comprising:
a first stage amplifier comprising memory cells in parallel and connecting to a bitline;
a second stage amplifier comprising a plurality of differential amplifiers connecting to a common node and receiving a voltage signal from the memory cells of the first stage amplifier; and
a reference unity gain amplifier receiving a voltage bias from the first stage amplifier and providing a reference voltage to the second stage amplifier through the common node, wherein the reference unity gain amplifier is connected to provide a reference voltage to the second stage amplifier.

14. The structure of claim 12, wherein the memory cells store one of two resistance values and the voltage bias is a middle range of the two resistance values.

15. The structure of claim 12, wherein the plurality of differential amplifiers is connected to a decoupling capacitor.

16. The structure of claim 14, wherein the decoupling capacitor connects to the reference unity gain amplifier.

17. The structure of claim 12, wherein the reference unity gain amplifier is shared amongst a plurality of differential amplifiers, and the plurality of differential amplifiers detects a difference in signals from the first stage amplifier and the reference unity gain amplifier.

18. The structure of claim 16, wherein a signal associated with the amplified difference is provided to a data line sense amplifier.

19. A method comprising:
providing a first signal form a first stage amplifier to a second stage amplifier, the second stage amplifier comprising a plurality of differential sense amplifiers;
providing a voltage bias from the first stage amplifier to a reference unity gain amplifier;
providing a second signal from the reference unity gain amplifier to the second stage amplifier, wherein the reference unity gain amplifier is connected to provide a reference voltage to the second stage amplifier;
sensing a difference between the first signal and the second signal in the second stage amplifier;
amplifying the sensed difference in the second stage amplifier; and
providing a signal to a data line sense amplifier based on the sensed difference.

20. The method of claim 19, further comprising decoupling the second signal from each of the plurality of differential sense amplifiers.
